(19) United States
(12) Patent Application Publication
(10) Pub. No.: US 2009/0011343 A1
(43) Pub. Date: Jan. 8, 2009

(54) MICROSTRUCTURE AND MANUFACTURING METHOD THEREOF

(76) Inventors: Hsin-Chang TSAI, Taoyuan Hsien (TW); Yu-Ru Chang, Taoyuan Hsien (TW); Tai-Kang Shing, Taoyuan Hsien (TW)

Correspondence Address: BIRCH STEWART KOLASCH & BIRCH, PO BOX 747, FALLS CHURCH, VA, 22040-0747, US

(21) Appl. No.: 12/211,709

(22) Filed: Sep. 16, 2008

Related U.S. Application Data
(62) Division of application No. 11/497,433, filed on Aug. 2, 2006.

(30) Foreign Application Priority Data
Sep. 9, 2005 (TW) 094130970

(51) Int. Cl. C23F 1/00; G03F 1/00

(52) U.S. Cl. 430/5; 216/41

(57) ABSTRACT

A microstructure includes a substrate and a photoresist layer. The substrate has a surface, and the photoresist layer is disposed on the substrate. The photoresist layer has at least one recess, which has a sidewall, a depth and a width. An oblique angle of the sidewall is not less than 5 degrees, and the aspect ratio is not less than 2. Also, a manufacturing method of the microstructure is also disclosed.

### CROSS REFERENCE TO RELATED APPLICATIONS

This Non-provisional application is a Divisional Application claiming the benefit of U.S. Non-provisional application Ser. No. 11/497,433 filed on Aug. 2, 2006, which claims priority on Application No. 094130970 filed in the Republic of China on Sep. 9, 2005, and entitled “MICROSTRUCTURE AND MANUFACTURING METHOD THEREOF,” the entire disclosure of which is hereby incorporated herein by reference for all purposes.

### BACKGROUND OF THE INVENTION

1. Field of Invention

The invention relates to a microstructure and a manufacturing method thereof, and, in particular, to a microstructure with a high aspect ratio and a manufacturing method thereof.

2. Related Art

The oblique sidewall structure is a very useful for a micro electromechanical system (MEMS). This structure is used to be a contact window plug, a dielectric layer window plug or applied to the precise mold-forming. The conventional manufacturing method of the oblique sidewall structure usually utilizes the mechanical process such as a milling process, a griding process, a laser process, an electro-discharging process, or the likes.

Please refer to FIGS. 1A to 1C, which show the steps of the conventional manufacturing method for forming the oblique sidewall structure of the MEMS. As shown in FIG. 1A, a workpiece 10 with a surface 101 is provided at first, while a tool 11 with an oblique surface 111 is chosen. Next, as shown in FIG. 1B, the tool 11 is used to process the surface 101 of the workpiece 10 by way of the cutting process, the griding process, the milling process, and the likes. Finally, as shown in FIG. 1C, a recess C1 with the oblique sidewall is formed on the workpiece 10 after the processes.

However, the above mentioned processes, which utilize the tools of limited sizes and precisions, cannot successfully form the oblique sidewall structure with high precision, high resolution and low surface roughness for MEMS application. Therefore, it is an important subject of the invention to provide a microstructure, which has high precision, high resolution, and low surface roughness, and a manufacturing method thereof in the MEMS.

### SUMMARY OF THE INVENTION

In view of the foregoing, the invention is to provide a microstructure with high precision, high resolution, and low surface roughness, and a manufacturing method thereof. Furthermore, the microstructure can be produced by a batch process so as to reduce the manufacturing time and cost.

To achieve the above, a microstructure of the invention includes a substrate and a photoresist layer. The substrate has a surface, and the photoresist layer is disposed on the surface of the substrate. The photoresist layer has at least one recess, which has a sidewall, a depth, and a width. In the invention, an oblique angle of the sidewall is not less than 5 degrees, and the aspect ratio of the recess is not less than 2.

To achieve the above, a manufacturing method of a microstructure of the invention includes the following steps of: providing a substrate, which has a surface with a roughness greater than 50 nm; disposing a photoresist layer on the substrate; providing a photo mask which has a predetermined pattern above the photoresist layer; exposing the photoresist layer to a light source through the photo mask; and removing a part of the photoresist layer to form at least one recess in the photoresist layer. In the invention, the recess has a sidewall, a depth, and a width. An oblique angle of the sidewall is not less than 5 degrees, and the aspect ratio of the recess is not less than 2.

To achieve the above, another manufacturing method of a microstructure of the invention includes the following steps of: providing a substrate which has a surface; disposing a photoresist layer on the substrate; providing a photo mask above the photoresist layer; providing a light source to have a first inclined angle with the photoresist layer, and Then exposing the photoresist layer to the light source through the photo mask; adjusting the light source or the photoresist layer to obtain a second inclined angle between the light source and the photoresist layer, and then exposing the photoresist layer to the light source through the photo mask; and removing a part of the photoresist layer to form at least one recess in the photoresist layer. In the invention, the recess has a sidewall, a depth, and a width. An oblique angle of the sidewall is not less than 5 degrees, and the aspect ratio of the recess is not less than 2.

To achieve the above, another manufacturing method of a microstructure of the invention includes the following steps of: providing a transparent substrate, which has a surface including at least one opaque area; disposing a photoresist layer on the surface of the transparent substrate; exposing the photoresist layer to a light source through the transparent substrate; and removing a part of the photoresist layer to form at least one recess in the photoresist layer. In the invention, the recess has a sidewall, a depth, and a width. An oblique angle of the sidewall is not less than 5 degrees, and the aspect ratio of the recess is not less than 2.

As mentioned above, in the microstructure and manufacturing method thereof of the invention, the invention is to form the photoresist layer on the substrate and then utilize a semiconductor process, such as the photolithographic process, to form the microstructure. Thus, the resolution, precision and surface roughness of the microstructure of the invention are much better than those of the conventional microstructure made by utilizing mechanical processes. Furthermore, the semiconductor process has the advantage of batch productions, which can reduce manufacturing time and cost.

### BRIEF DESCRIPTION OF THE DRAWINGS

The invention will become more fully understood from the detailed description given herein below illustration only, and thus is not limitative of the present invention, and wherein:

FIGS. 1A to 1C are schematic illustrations showing the manufacturing steps of oblique sidewall structure in the conventional MEMS;

FIG. 2 is a schematic view of a microstructure according to a preferred embodiment of the invention;

FIG. 3 is a schematic view of another microstructure according to the preferred embodiment of the invention;

FIGS. 4A to 4E are schematic illustrations showing a manufacturing method of a microstructure according to a first embodiment of the invention;

FIGS. 5A to 5F are schematic illustrations showing a manufacturing method of a microstructure according to a second embodiment of the invention;

FIGS. 6A to 6D are schematic illustrations showing a manufacturing method of a microstructure according to a third embodiment of the invention; and

FIGS. 7A to 7D are schematic illustrations showing a manufacturing method of a microstructure according to a fourth embodiment of the invention.

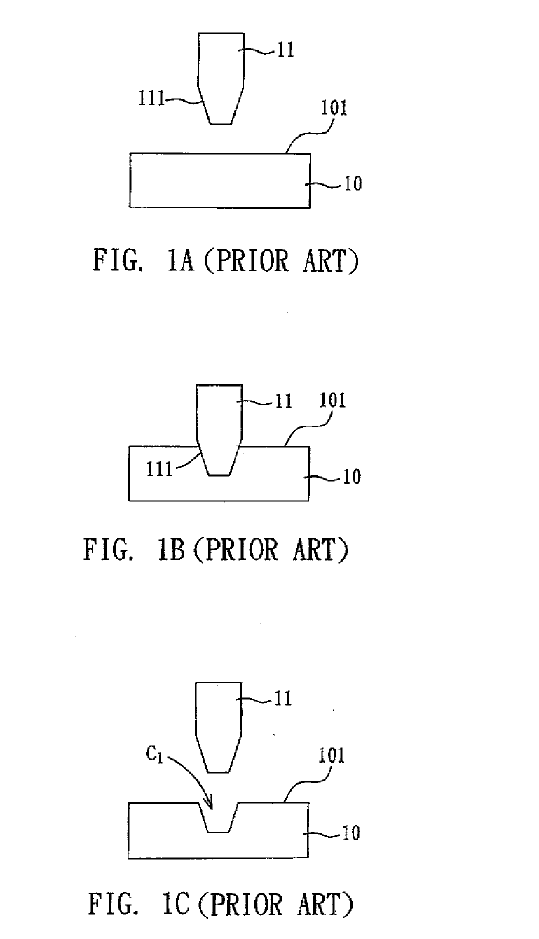

### DETAILED DESCRIPTION OF THE INVENTION

The present invention will be apparent from the following detailed description, which proceeds with reference to the accompanying drawings, wherein the same references relate to the same elements.

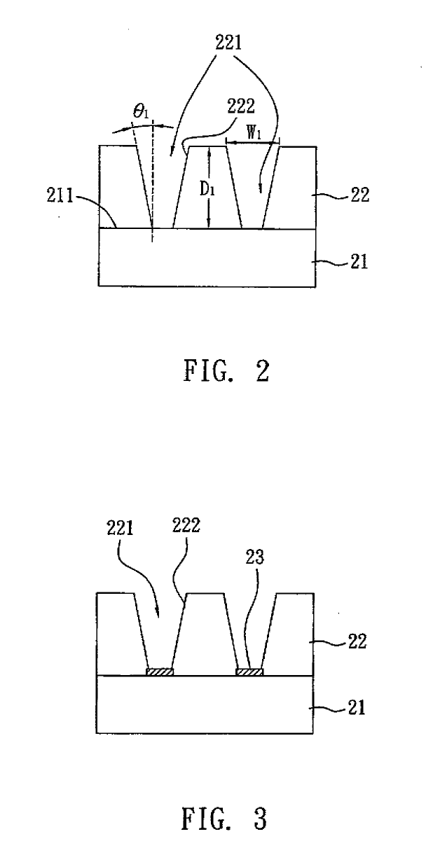

With reference to FIG. 2, a microstructure according to a preferred embodiment of the invention is applied to a MEMS and includes a substrate 21 and a structure layer 22.

The substrate 21 has a surface 211. In this embodiment, the substrate 21 can be a transparent substrate, a semi-transparent substrate, or an opaque substrate. The surface 211 has a roughness which is preferably greater than about 50 nm, but it is not limited thereto.

The structure layer 22 is disposed on the surface 211 of the substrate 21. In addition, the structure layer 22 has at least one recess 221 which has a sidewall 222, a depth D1, and a width W1. Herein, an oblique angle θ1 of the sidewall 222 is preferably not less than 5 degrees, and the aspect ratio of the recess 221 (i.e. the ratio of the depth D1 to the width W1 of the recess 221) is preferably not less than 2. The recess 221 has a feature size which is preferably not greater than 0.5 mm, and a processing accuracy of the recess 221 is preferably not greater than 0.01 mm. Besides, the recess 221 may have two sidewalls 222, and the sidewalls 222 are disposed symmetrically or asymmetrically. In practice, the oblique angle θ1 of the sidewall 222 of the recess 221 may be changed depending on the actual needs.

In the present embodiment, the depth D1 is preferably not less than 0.03 mm. Following to the defined aspect ratio that should be preferably not less than 2, the width W1 must be preferably not greater than 0.015 mm. To form the structure layer 22 of the embodiment, a photoresist layer (not shown) is provided in advance, an exposing process and a developing process are then performed, and the photoresist layer is finally removed. Alternatively, the structure layer 22 of the embodiment can be a photoresist layer, which is made of a positive photosensitive material, a negative photosensitive material, a single-layer photosensitive material or a multi-layer photosensitive material. However, the above-mentioned material is not limited thereto. In practice, the invention can use any suitable photosensitive material and the proper layer number depending on the actual needs.

With reference to FIG. 3, when the substrate 21 of the microstructure is a transparent substrate or a semi-transparent substrate, a bottom surface of the recess 221 includes an opaque area 23 disposed on the surface 211 of the substrate 21. Herein, the residual features of the microstructure as shown in FIG. 3 are the same as those of the previously mentioned one (as shown in FIG. 2), so the detailed descriptions are omitted for concise purpose.

To make the invention more comprehensive, the manufacture method of a microstructure according to four embodiments of the invention will be described hereinafter with reference to the accompanying drawings.

### FIRST EMBODIMENT

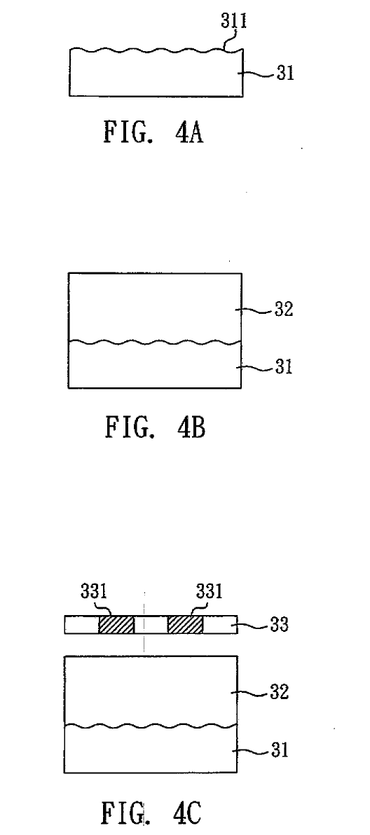

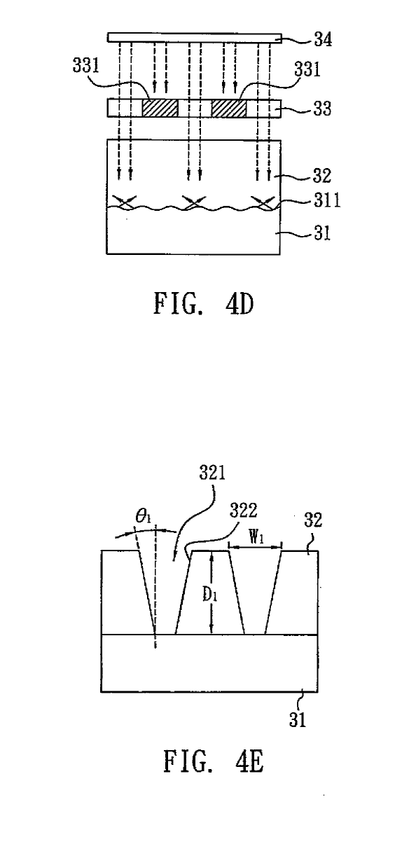

A manufacture method of a microstructure according to a first embodiment of the invention includes the following steps. With reference to FIG. 4A, a substrate 31 with a surface 311, which has a roughness greater than 50 nm, is firstly provided. In this embodiment, the surface 311 of the substrate 31 is processed with a surface treatment process to form a rough surface. The surface treatment process is, for example, a sand-blasting process, a electro-discharging process, a laser blasting process, a plasma etching process, or a chemical etching process. Alternatively, the substrate 31 may further include an uneven layer (not shown) disposed on the surface 311 of the substrate 31. The roughness of the uneven layer is preferably greater than 50 nm, and the uneven layer may be manufactured by the surface deposition or treatment process.

Next, referring to FIG. 4B, a photoresist layer 32 is formed on the surface 311 of the substrate 31. In the current embodiment, the photoresist layer 32 is made of a negative photosensitive material, and the thickness of the photoresist layer 32 is not less than 0.03 mm.

Referring to FIG. 4C, a photo mask 33, which has a predetermined pattern 331, is then provided above the photoresist layer 32. In this embodiment, the predetermined pattern 331 of the photo mask 33 is an opaque predetermined pattern.

After that, with reference to FIG. 4D, a light source 34 is provide and the photoresist layer 32 is exposed to the light source 34 through the photo mask 33.

Finally, as shown in FIG. 4E, a part of the photoresist layer 32 is removed to form at least one recess 321, which has a sidewall 322, a depth D1, and a width W1, in the photoresist layer 32. In the embodiment, an oblique angle θ1 of the sidewall 322 is not less than 5 degrees, and the aspect ratio is not less than 2. The recess 321 of the embodiment is formed by a photolithographic process. Since the photoresist layer 32 is made of a negative photosensitive material, the part of the photoresist layer 32, which is not exposed to the light source 34, forms the recess 321 after the photolithographic process. Herein, the photolithographic process is a commonly used semiconductor manufacturing process, so the detailed descriptions are omitted. In the embodiment, the depth D1 of the recess 321 and the thickness of the photoresist layer 32 are the same (0.03 mm). Following to the defined aspect ratio that should be not less than 2, the width W1 of the recess 321 must be not greater than 0.015 mm. In this case, the recess 321 has a feature size not greater than 0.5 mm and a processing accuracy not greater than 0.01 mm. Besides, when the light emitted from the light source 34 reaches the rough surface 311 of the substrate 31, a scattering phenomenon is generated so that the light becomes scattered light, which irradiates the photoresist layer 32 to form the oblique angle θ1 of the recess 321.

### SECOND EMBODIMENT

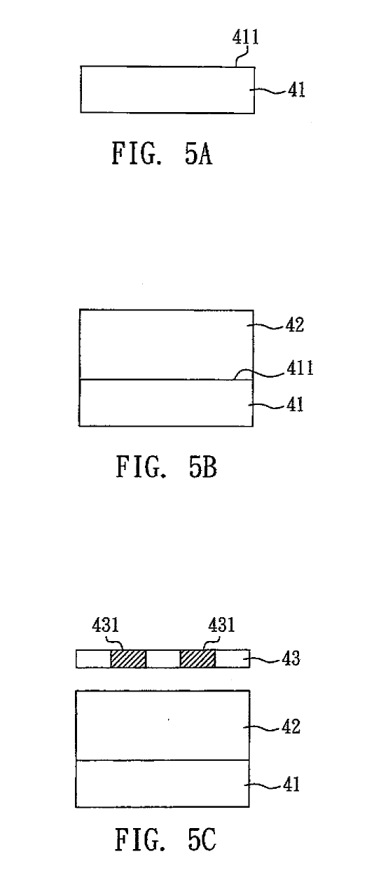

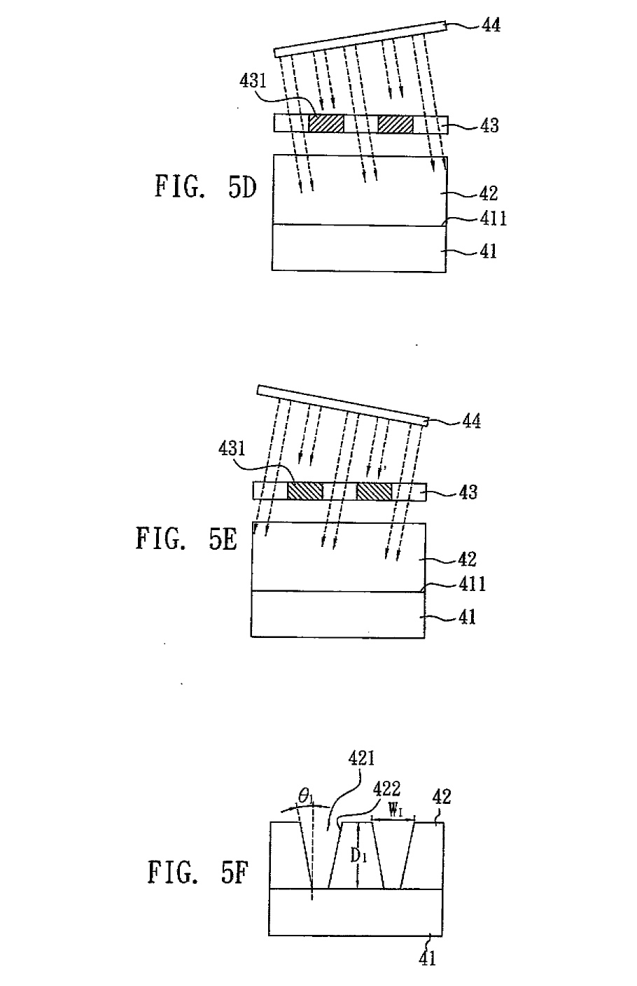

A manufacture method of a microstructure according to a second embodiment of the invention includes the following steps. With reference to FIG. 5A, a substrate 41 with a surface 411 is firstly provided.

Referring to FIG. 5B, a photoresist layer 42 is then formed on the surface 411 of the substrate 41. In the current embodiment, the photoresist layer 42 is made of a negative photosensitive material, and the thickness of the photoresist layer 42 is not less than 0.03 mm.

Referring to FIG. 5C, a photo mask 43, which has a predetermined pattern 431, is then provided above the photoresist layer 42. In this embodiment, the predetermined pattern 431 of the photo mask 43 is an opaque predetermined pattern.

After that, with reference to FIG. 5D, a light source 44 is provide to have a first inclined angle with the photoresist layer 42, and the light emitted from the light source 44 then irradiates the photoresist layer 42 through the photo mask 43.

With reference to FIG. 5E, the light source 44 is adjusted to have a second inclined angle with the photoresist layer 42, and the light emitted from the light source 44 then irradiates the photoresist layer 42 through the photo mask 43. In the present embodiment, the first inclined angle and the second inclined angle can be formed by a way of adjusting a position or angle of the light source. In addition, the first and second inclined angles can also be formed by a way of adjusting a position or angle of the photoresist layer 42 and the substrate 41.

Finally, as shown in FIG. 5F, a part of the photoresist layer 42 is removed to form at least one recess 421, which has a sidewall 422, a depth D1, and a width W1, in the photoresist layer 42. In the embodiment, an oblique angle θ1 of the sidewall 422 is not less than 5 degrees, and the aspect ratio is not less than 2. The recess 421 of the embodiment is formed by a photolithographic process. Since the photoresist layer 42 is made of a negative photosensitive material, the part of the photoresist layer 42, which is not exposed to the light source 44, forms the recess 421 after the photolithographic process. In the embodiment, the depth D1 of the recess 421 and the thickness of the photoresist layer 42 are the same (0.03 mm). Following to the defined aspect ratio that should be not less than 2, the width W1 of the recess 421 must be not greater than 0.015 mm. In this case, the recess 421 has a feature size not greater than 0.5 mm and a processing accuracy not greater than 0.01 mm.

### THIRD EMBODIMENT

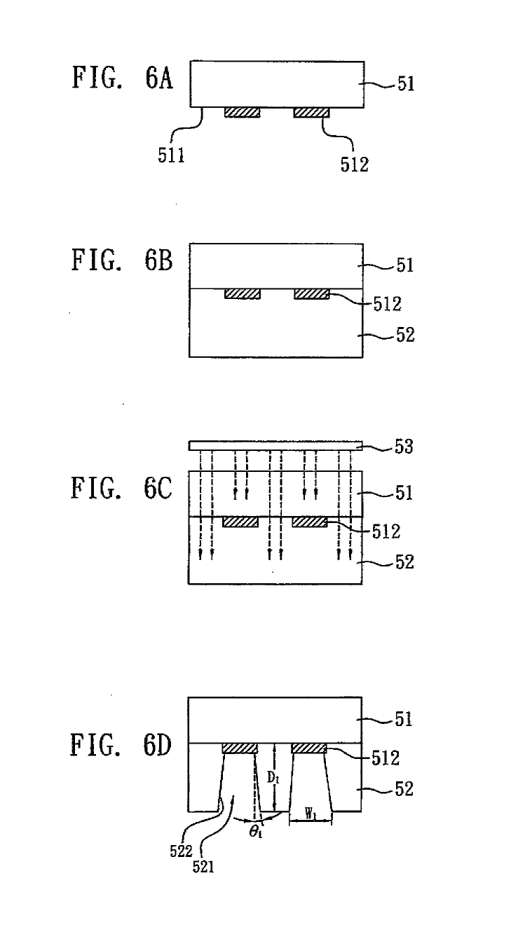

A manufacture method of a microstructure according to a third embodiment of the invention includes the following steps. With reference to FIG. 6A, a transparent substrate 51 with a surface 511 is firstly provided. The transparent substrate 51 further includes an opaque area 512 disposed on the surface 511.

Referring to FIG. 6B, a photoresist layer 52 is then formed on the surface 511 of the transparent substrate 51. In the current embodiment, the photoresist layer 52 is made of a negative photosensitive material, and the thickness of the photoresist layer 52 is not less than 0.03 mm.

After that, with reference to FIG. 6C, a light source 53 is provide to irradiate the transparent substrate 51 through the photoresist layer 52, and the photoresist layer 52 can be exposed to the light source 53.

Finally, as shown in FIG. 6D, a part of the photoresist layer 52 is removed to form at least one recess 521, which has a sidewall 522, a depth D1, and a width W1, in the photoresist layer 52. In the embodiment, an oblique angle θ1 of the sidewall 522 is not less than 5 degrees, and the aspect ratio is not less than 2. The recess 521 of the embodiment is formed by a photolithographic process. Since the photoresist layer 52 is made of a negative photosensitive material, the part of the photoresist layer 52, which is not exposed to the light source 53, forms the recess 521 after the photolithographic process. In the embodiment, the depth D1 of the recess 521 and the thickness of the photoresist layer 52 are the same (0.03 mm). Following to the defined aspect ratio that should be not less than 2, the width W1 of the recess 521 must be not greater than 0.015 mm. In this case, the recess 521 has a feature size not greater than 0.5 mm and a processing accuracy not greater than 0.01 mm. Besides, when the light emitted from the light source 53 reaches the opaque area 512, a diffraction phenomenon or a refraction phenomenon is generated so that the light becomes the diffracted/refracted light, which irradiates the photoresist layer 52 to form the oblique angle θ1 of the recess 521.

### FOURTH EMBODIMENT

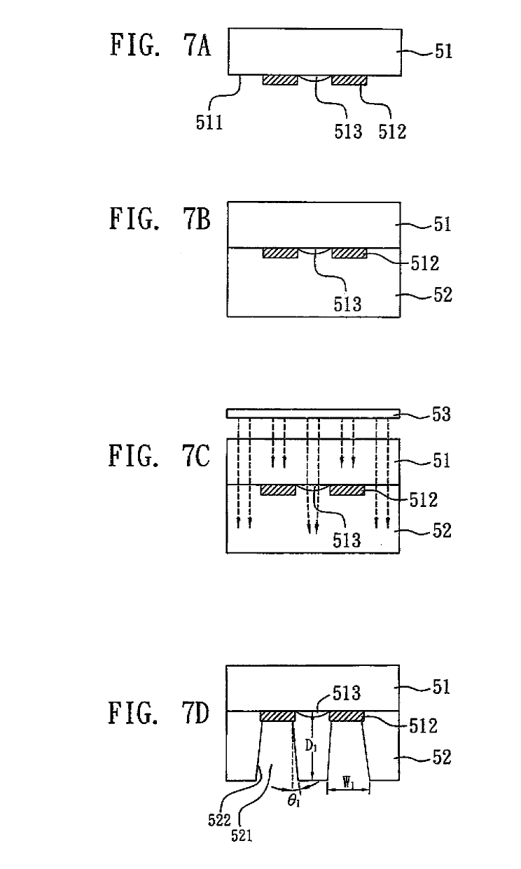

A manufacture method of a microstructure according to a fourth embodiment of the invention is illustrated with reference to FIGS. 7A to 7D. Most of the steps of the fourth embodiment are the same as those of the third embodiment, so the detailed descriptions are omitted. In the current embodiment, the surface 511 has a transparent area and there is a lens 513 located at the transparent area, which is different from the previous third embodiment. The lens 513 can focus the light after the light passing through it. Thus, when the light emitted from the light source 53 irradiates the photoresist layer 52, as shown in FIG. 7C, the light is focused by the lens 513. Accordingly, the step of removing a part of the photoresist layer 52 can be controlled so as to obtain the oblique angle θ1 of the sidewall 522.

In summary, in the microstructure and manufacturing method thereof of the invention, the invention is to form the photoresist layer on the substrate and then utilize a semiconductor process, such as a photolithographic process, to form the microstructure. Thus, the resolution, precision and surface roughness of the microstructure of the invention are much better than those of the conventional microstructure made by utilizing mechanical processes. Furthermore, the semiconductor process has the advantage of batch productions, which can reduce manufacturing time and cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method of a microstructure, comprising steps of:
providing a substrate;
disposing a photoresist layer on the surface of the substrate;
exposing the photoresist layer to a light source; and
removing a part of the photoresist layer to form at least one recess in the photoresist layer to form the microstructure.

2. The method of claim 1, wherein the recess has a sidewall, a depth, and a width, and a ratio of the depth to the width is not less than 2.

3. The method of claim 1, wherein the recess has a feature size not greater than 0.5 mm.

4. The method of claim 1, wherein a processing accuracy of the recess is not greater than 0.01 num.

5. The method of claim 1, wherein the thickness of the photoresist layer is not less than 0.03 mm.

6. The method of claim 2, wherein an oblique angle of the sidewall is not less than 5 degrees.

7. The method of claim 2, wherein the depth is not less than 0.03 mm.

8. The method of claim 2, wherein the width is not greater than 0.015 mm.

9. The method of claim 1, wherein the recess has two sidewalls, and the sidewalls are disposed symmetrically or asymmetrically.

10. The method of claim 1, wherein the photoresist layer is made of a positive photosensitive material, a negative photosensitive material, a single-layer photosensitive material or a multi-layer photosensitive material.

11. The method of claim 1, wherein the substrate has a transparent substrate, a semi-transparent substrate, an opaque substrate, or a surface comprising an opaque area and a transparent area.

12. The method of claim 11, wherein the recess is formed on the opaque area of the surface of the substrate.

13. The method of claim 11, wherein the step of exposing the photoresist layer to the light source is by exposing the photoresist layer to the light source from the substrate through the transparent area of the substrate to the photoresist layer.

14. The method of claim 11, wherein the recess is formed by a photolithographic process, a light emitted from the light source through the substrate reaches the opaque area and the transparent area of the surface of the substrate so as to become diffracted light and/or refracted light, and the oblique angle of the sidewall of the recess is formed by the diffracted light and/or the refracted light.

15. The method of claim 11, further comprising a step of providing a lens located at the transparent area of the substrate.

16. The method of claim 15, wherein a light emitted from the light source through the substrate reaches the opaque area and the transparent area of the surface of the substrate so as to become diffracted light and/or refracted light, the lens focuses the light after the light passes through the lens, and the oblique angle of the sidewall of the recess is formed by the diffracted light and/or the refracted light.
